(19) United States
(12) Patent Application Publication
(10) Pub. No.: US 2007/0133635 A1
(43) Pub. Date: Jun. 14, 2007

(54) Dual light source and laser projection display apparatus using same

(75) Inventor: Du-Chang Heo, Suwon-si (KR)

Correspondence Address: CHA & REITER, LLC, 210 ROUTE 4 EAST STE 103, PARAMUS, NJ, 07652, US

(73) Assignee: Samsung Electronics Co.; LTD

(21) Appl. No.: 11/499,361

(22) Filed: Aug. 4, 2006

(30) Foreign Application Priority Data
Dec. 14, 2005 (KR) 2005-123482

(51) Int. Cl. H01S 5/00

(52) U.S. Cl. 372/43.01

(57) ABSTRACT

Disclosed is a laser projection display apparatus. The laser projection display apparatus includes a green light source for generating green light having a predetermined wavelength, and a dual light source in which at least two semiconductor lasers are integrated and generate red and blue lights of predetermined wavelengths. The apparatus further includes a means for orienting and collimating the generated lights.

### CLAIM OF PRIORITY

This application claims the benefit of the earlier filing date, pursuant to 35 USC 119, to that patent application entitled “Dual Light Source and Laser Projection Display Apparatus Using the Same,” filed with the Korean Intellectual Property Office on Dec. 14, 2005 and assigned Serial No. 2005-123482, the contents of which are incorporated herein by reference.

### BACKGROUND OF THE INVENTION

1. Field of the Invention

The present invention relates to a laser projection display apparatus and more particularly to a portable laser projection display apparatus including a spatial light modulator.

2. Description of the Related Art

Recently, a laser projection display apparatus using a laser light source such as a semiconductor laser and the like has been proposed. The laser projection display apparatus having the laser light source can be used for a projector, a projection television, a color scanner, a color printer, etc. Where the laser projection display apparatus including the laser light source is used for the projector or the projection television, the laser projection display apparatus displays images on a screen. On the other hand, where the laser projection display apparatus is used for the color printer or the color scanner, the laser projection display apparatus projects images on the surface of a drum of the color printer or the color scanner.

The laser projection display apparatus includes laser sources, such as semiconductor lasers, for generating light having different wavelengths, and a spatial light modulator for emitting the light to each pixel according to a control signal of a controller. Various types of spatial light modulators can be used for the laser projection display apparatus.

Diffraction grids which can modulate the characteristics of incident light are generally used as the spatial light modulators. Specifically, for such diffraction grids, U.S. Pat. No. 5,459,610, issued to David M. Bloom, et al. on Oct. 17, 1995, discloses a grating light valve (GLV) for use as a spatial light modulator, and U.S. Pat. No. 6,476,848, issued to Kowarz, et al. on Nov. 5, 2002, discloses a grating electromechanical system (GEMS).

In addition, U.S. Pat. No. 6,088,102, issued to Paul K. Manhart, et al. on Jul. 11, 2000, discloses a laser projection display apparatus using a grating light valve (GLV). Further, U.S. Pat. No. 6,724,515, issued to Kowarz, et al. on Apr. 20, 2004, discloses a laser projection display apparatus using a grating electromechanical system.

Laser projection display apparatuses use light of the three primary colors of red, blue and green. However, since the semiconductor laser cannot yet facilitate direct generation of green color, a secondary harmonic generator, etc. is used for generating the green light. Each wavelength light is transmitted through a separate pathway into the spatial light modulator. A plurality of optical elements including a lens system for collimating the light having a predetermined wavelength is disposed between the spatial light modulator and each light source.

However, the scanning units have disadvantages of having a large volume and a large electrical consumption, making it impossible for a user to carry them.

### SUMMARY OF THE INVENTION

Accordingly, the present invention has been made to solve the above-mentioned problems occurring in the prior art and provides additional advantages, by providing a laser projection display apparatus which has a small volume and is applicable to a portable terminal.

According to an aspect of the present invention, there is provided a laser projection display apparatus which comprises a green light source for generating green light having a predetermined wavelength and a dual light source in which at least two semiconductor lasers are integrated and generate red and blue lights having predetermined wavelengths.

According to another aspect of the present invention, there is provided a dual light source for generating at least two kinds of lights having different wavelengths from each other, which comprises a sub-mount, and at least two semiconductor lasers disposed and spaced at a predetermined distance from each other on the sub-mount, for generating lights having different wavelengths from each other.

### BRIEF DESCRIPTION OF THE DRAWINGS

The above features and advantages of the present invention will be more apparent from the following detailed description taken in conjunction with the accompanying drawings, in which:

FIG. 1 is a view showing the structure of a laser projection display apparatus according to the first embodiment of the present invention;

FIGS. 2A to 2E are graphs illustrating the operation of a spatial light modulator shown in FIG. 1 which scans light in a line pattern;

FIG. 3 is a view showing dual light sources according to a second embodiment of the present invention; and

FIG. 4 is a view showing dual light sources according to a third embodiment of the present invention.

### DETAILED DESCRIPTION OF THE INVENTION

Hereinafter, the embodiments of the present invention will be described with reference to the accompanying drawings. For the purposes of clarity and simplicity, a detailed description of known functions and configurations incorporated herein is omitted to avoid making the subject matter of the present invention unclear.

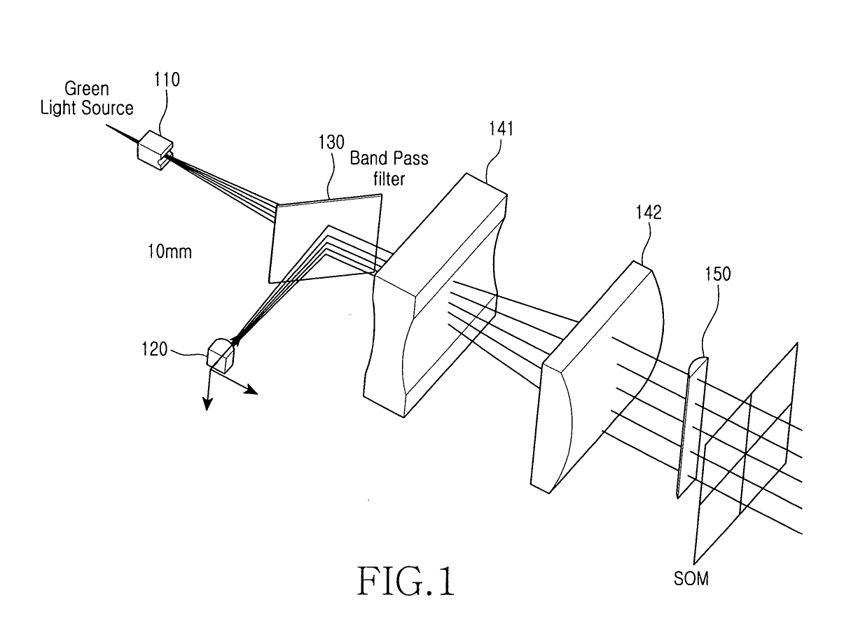

FIG. 1 is a view showing the structure of a laser projection display apparatus according to a first embodiment of the present invention.

Referring to FIG. 1, the laser projection display apparatus includes a green light source 110 for generating green light having a predetermined wavelength, a dual light source 120 in which at least two semiconductor lasers are integrated and generate red and blue lights having predetermined wavelengths, respectively, a band pass filter 130 for transmitting the green light and changing a pathway for the red and blue lights by an angle of 90 degrees, first and second lenses 141 and 142 for collimating the green, red and blue lights, and a spatial light modulator 150 for scanning the lights collimated by the first and second lenses in a line pattern. In the laser projection display apparatus according to the present embodiment, the dual light source 120 and the green light source 110 may be arranged at positions opposite to those shown in FIG. 1.

The green light source 110 does not allow easy direct modulation by using a solid laser or the like. Therefore, the green light source 110 may include a laser for generating light having an infrared wavelength band and a secondary harmonic generator for converting the light having the infrared wavelength band into the green light having a predetermined wavelength.

The dual light source 120 may have a structure in which semiconductor lasers capable of generating lights having different wavelengths are horizontally arranged on a substrate side by side, or a structure in which the semiconductor lasers are symmetrically arranged on both surfaces of the substrate. In the dual light source according to the present embodiment, the semiconductor lasers capable of generating red light having a predetermined wavelength and blue light having a predetermined wavelength are integrated.

A dielectric thin film in which a plurality of dielectric materials are multiply stacked can be used as the band pass filter 130 which transmits the green light and reflects the red and blue lights in a direction perpendicular to an incident pathway so as to introduce the red and blue lights into the first lens 141. The first and second lenses 141 and 142 collimate and output the incident light toward the spatial optical modulator 150.

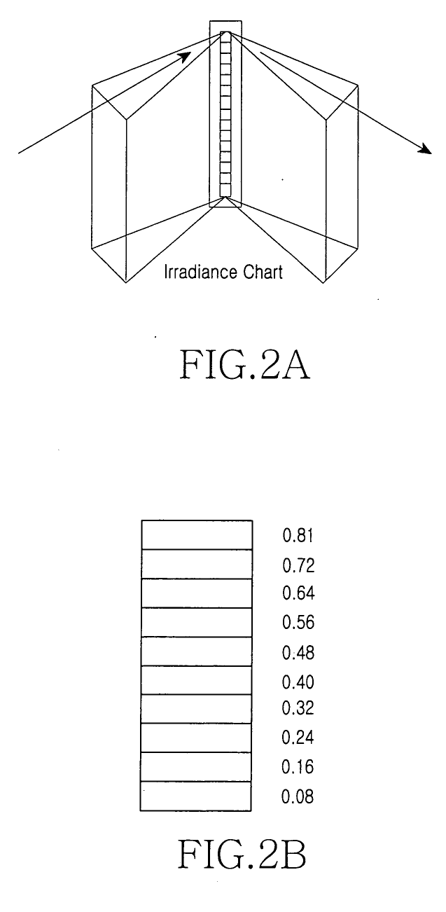

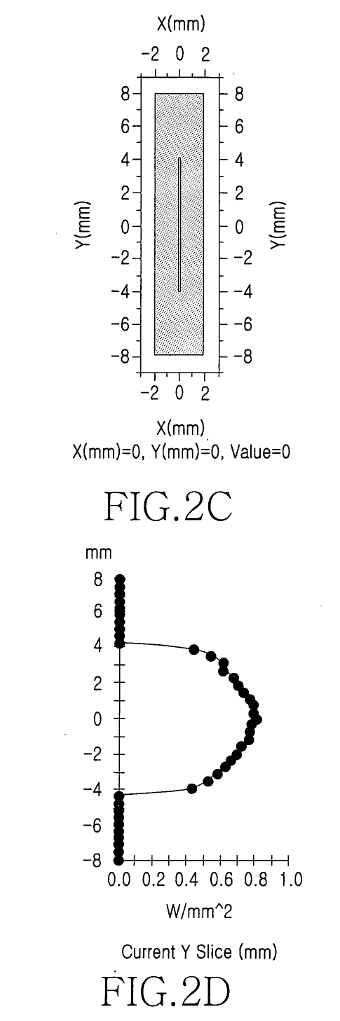

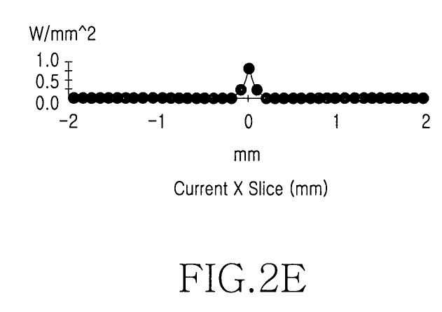

FIGS. 2A to 2E are graphs illustrating the operation of the spatial light modulator 150 for scanning the light in the line patterns. The spatial light modulator 150 can scan the light, which is incident from the second lens 142 and collimated, in the line patterns as shown in FIGS. 2A to 2E. The spatial light modulator 150 can collimate the blue and red lights with a spacing at a distance larger than 200 μm from each other.

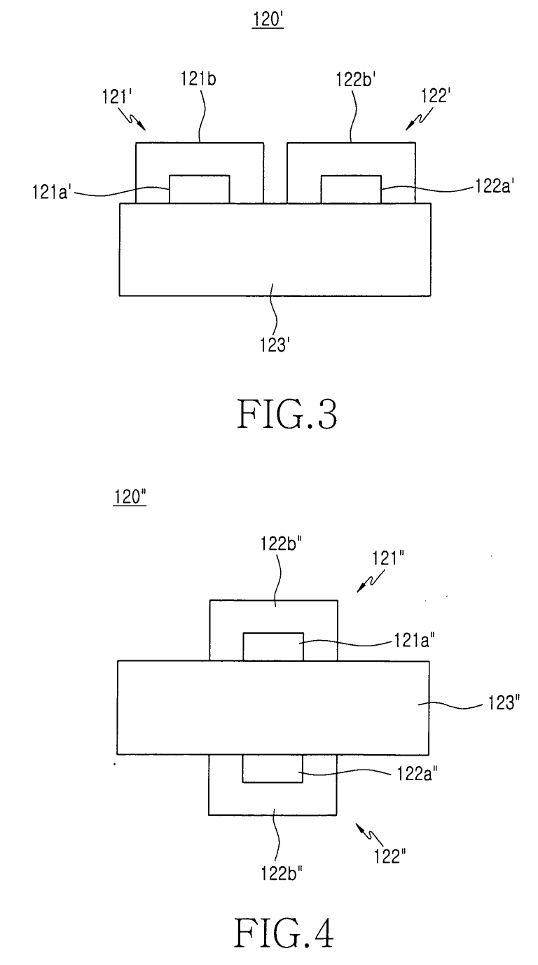

FIG. 3 is a view showing the dual light source according to a second embodiment of the present invention. Referring to FIG. 3, the dual light source 120′ according to this embodiment of the present invention includes a sub-mount 123′ and at least two semiconductor lasers 121′ and 122′ capable of generating light in different wavelength bands. The semiconductor lasers 121′ and 122′ are horizontally arranged on the sub-mount 123′ side by side. Each semiconductor laser 121′ or 122′ includes an active layer 121a′ or 122a′, and a clad 121b′ or 122b′ surrounding the active layer 121a′ or 122a′, respectively. The semiconductor lasers 121′ and 122′ are spaced at a distance less than 500 μm from each other. Preferably, the semiconductor lasers 121′ and 122′ can be spaced at a distance in a range of 120 to 500 μm from each other.

FIG. 4 is a view showing a dual light source 120″ according to a third embodiment of the present invention.

Referring to FIG. 4, the dual light source 120″ according to this embodiment of the present invention includes a sub-mount 123″ and at least two semiconductor lasers 121″ and 122″ capable of generating their light in different wavelength bands. The semiconductor lasers 121″ and 122″ are symmetrically disposed on upper and lower surfaces of the sub-mount 123″. Each semiconductor laser 121″ or 122″ includes an active layer 121a″ or 122a″ for generating light having a predetermined wavelength, and a clad 121b″ or 122b″ surrounding the active layer 121a″ or 122b″, respectively. The sub-mount 123″ is formed to have a thickness of 500 μm.

Since the dual light source, in which the semiconductor lasers capable of generating the red and blue lights respectively are integrated, can be used for the laser projection display apparatus, the present invention has an advantage of providing a laser projection display apparatus which is miniaturized. Specifically, the dual light source according to the present invention has a single optical pathway for both the red and blue lights, which share optical elements in the optical pathway, instead of using respective pathways corresponding to the red light and the blue light. Therefore, it is possible to minimize the volume of the laser projection display apparatus and construct the laser projection display apparatus by using a reduced number of elements.

Particularly, in the laser projection display apparatus including the semiconductor laser capable of generating the red and blue lights, the light source can be constructed with a reduced number of elements from three to two. Further, the number of band pass filters for the laser projection display apparatus can be reduced from at least two to one. Accordingly, a space in which units used for jointing light can be reduced by about one centimeter. For example, the volume of a conventional laser projection display apparatus, i.e. 3 cm×5 cm×1 cm, i.e., 15 cc, can be reduced to 8 cc, i.e. 2 cm×4 cm×1 cm.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A dual light source for generating at least two kinds of lights each having different wavelengths, comprising:
a sub-mount; and
at least two semiconductor lasers disposed and spaced at a predetermined distance from each other on the sub-mount, the at least two lasers generating lights having different wavelengths from each other.

2. The dual light source as claimed in claim 1, wherein the semiconductor lasers are spaced at a distance less than 500 μm from each other.

3. The dual light source as claimed in claim 1, wherein each semiconductor laser includes:
an active layer; and
a clad formed on the sub-mount surrounding a corresponding active layer.

4. A dual light source comprising:
a sub-mount; and
at least two semiconductor lasers, at least one disposed on a upper surface and at least one disposed on a lower surface of the sub-mount and spaced at a distance less than 500 μm from each other, for generating lights having different wavelengths from each other.

5. A laser projection display apparatus comprising:
a green light source for generating green light of a predetermined wavelength; and
a dual light source in which at least two semiconductor lasers are integrated and generate red and blue lights of a predetermined wavelengths.

6. The laser projection display apparatus as claimed in claim 5, further comprising:
a band pass filter for passing the green light and changing an orientation of the red and blue lights by an angle of 90 degrees;
first and second lenses for collimating the green, red and blue lights; and
a spatial light modulator for scanning the lights collimated by the first and second lenses in a line pattern.

7. The laser projection display apparatus as claimed in claim 5, wherein the red and blue lights generated by respective semiconductor lasers are spaced at a distance less than 500 μm from each other.

8. The laser projection display apparatus as claimed in claim 5, wherein the dual light source comprises:
at least one laser disposed on a upper surface and at least one laser disposed on a lower surface of a sub-mount and spaced at a distance less than 500 μm from each other.

9. A laser projection system comprising:
a laser light source for generating a green light in a first direction;
a dual-laser light source generating a blue and red light, the dual-laser light source positioned to generate the blue and red light in a direction substantially perpendicular to the first direction;
a prism for passing the green light along the first direction and changing the orientation of the blue and red light to travel along the first direction;
a first and second for collimating the green, red and blue lights; and
a spatial light modulator for scanning the green, red and blue lights collimated by the first and second lenses in a line pattern.

10. The laser projection display system as claimed in claim 9, wherein the dual light source comprises:
at least one laser is disposed on a upper surface and at least one laser disposed on a lower surface of a sub-mount and spaced at a distance less than 500 μm from each other.

11. The laser projection display system as claimed in claim 9, wherein the dual light source comprises:
at least one laser for generating the blue light and for generating the red light on a surface of a sub-mount and spaced at a distance less than 500 μm from each other.

12. The laser projection display system as claimed in claim 9, wherein the green light is generated by a second harmonic generation of a laser light of a non-green color.
